(19) United States
(12) Patent Application Publication
(10) Pub. No.: US 2008/0001234 A1
(43) Pub. Date: Jan. 3, 2008

(54) Hybrid Field Effect Transistor and Bipolar Junction Transistor Structures and Methods for Fabricating Such Structures

(76) Inventors: Kangguo Cheng, Beacon, NY (US); Louis Lu-Chen Hsu, Fishkill, NY (US); Jack Allan Mandelman, Flat Rock, NC (US)

Correspondence Address: WOOD, HERRON & EVANS, L.L.P. (IBM), 2700 CAREW TOWER, 441 VINE STREET, CINCINNATI, OH, 45202, US

(21) Appl. No.: 11/427,962

(22) Filed: Jun. 30, 2006

(51) Int. Cl. H01L 29/76

(52) U.S. Cl. 257/370

(57) ABSTRACT

Semiconductor device structures that integrate field effect transistors and bipolar junction transistors on a single substrate, such as a semiconductor-on-insulator substrate, and methods for fabricating such hybrid semiconductor device structures. The field effect and bipolar junction transistors are fabricated using adjacent electrically-isolated semiconductor bodies. During fabrication of the device structures, certain fabrication stages strategically rely on block masks for process isolation. Other fabrication stages are shared during the fabrication process for seamless integration that reduces process complexity.

### FIELD OF THE INVENTION

The invention relates generally to semiconductor device structures and fabrication methods and, in particular, to semiconductor device structures that integrate field effect transistors and bipolar junction transistors on a single substrate and methods of fabricating such hybrid semiconductor device structures.

### BACKGROUND OF THE INVENTION

Planar bipolar complementary metal oxide semiconductor (BiCMOS) type integrated circuits combine the advantages of bipolar junction transistors (BJT's) and field effect transistors (FET's) on a single substrate. For certain applications, the advantages of this integration justify the increased fabrication complexity and cost. Bipolar junction transistors provide faster switching speeds, higher current drive, and have advantages for analog applications, such as better device matching, than field effect transistors. On the other hand, field effect transistors have been in the mainstream of device fabrication where high density and low-power are important in integrated circuit design. By combining field effect transistors and bipolar junction transistors on a single substrate, integrated circuit designers can reap the advantages of each technology, namely speed performance competitive with bipolar junction transistor technology and integration density near that of field effect transistor technology.

Bipolar junction transistors are active semiconductor devices formed by a pair of P-N junctions, namely an emitter-base junction and a collector-base junction. An NPN bipolar junction transistor has a thin region of P-type material constituting the base region between two regions of N-type material constituting the emitter and collector regions. A PNP bipolar junction transistor has a thin region of N-type material constituting the base region between two regions of P-type material constituting the emitter and collector regions. The movement of electrical charge carriers that produces electrical current flow between the collector region and the emitter region is controlled by a voltage applied across the emitter-base junction.

Conventional bipolar junction transistors are fabricated with a vertical arrangement of the emitter, base, and collector regions in which these regions have a stacked planar construction formed on a planar surface. As a result, conventional bipolar junction transistors have a relatively large footprint that consumes a significant surface area of the active device layer. The device footprint cannot be reduced because the area of the emitter-base junction cannot be easily scaled. Consequently, the emitter-base junction in planar device designs is limited by the planar surface area.

Planar field effect transistors include a gate electrode overlying a channel region defined in a semiconductor substrate and a gate dielectric physically separating the gate electrode from the semiconductor material of the channel region. The channel region and gate electrode are flanked on opposite sides by highly-doped source and drain regions also defined in the semiconductor substrate. In operation, a bias potential applied to the gate electrode creates an electric field in the channel region of the substrate, which inverts a thin portion of the channel region to a conductive state underneath the gate dielectric and permits minority carriers to travel as an electric current through the channel region between the source and drain regions.

Complimentary metal oxide semiconductor (CMOS) transistors are common field effect transistors present in integrated circuits. A CMOS transistor may be characterized as either an n-channel field effect transistor (NMOS) with an n-type channel region under its gate electrode or a p-channel field effect transistor (PMOS) with a p-type channel region under its gate electrode. N-channel field effect transistors rely on electrons as charge carriers for the gated electrical current. The oppositely doped P-channel field effect transistors rely on holes as charge carriers for the gated electrical current. A CMOS integrated circuit integrates both n-channel field effect transistors and p-channel field effect transistors.

The continued scaling of CMOS transistor technology offers vastly superior performance to bipolar junction transistor technology. However, with the emergence of heterojunction bipolar transistors fabricated with a graded silicon-germanium layer in the base, bipolar junction transistors have maintained a lead in areas where ultra-high frequency response, bandwidth and low noise are important. Applications for heterojunction bipolar transistors include wireless and millimeter-wave communications areas.

Progressive miniaturization of feature sizes in planar CMOS transistors has improved the performance and increased the functional capability of integrated circuits. Despite the achievements in planar device scaling, fin-type field effect transistors (FinFETs) represent low-power, high speed devices that can be more densely packed than planar CMOS transistors. A conventional FinFET structure includes a narrow vertical fin of single crystal semiconductor material and a gate electrode that intersects a channel region of the fin. The gate electrode is isolated electrically from the fin by a thin dielectric layer. Flanking the central channel region on opposite ends of the vertical fin are source and drain regions. Because of the fabrication process, the fin has a width that is less than the minimum lithographic dimension and a relatively high aspect ratio. Despite their advantages, FinFETs have not been successfully integrated into BiCMOS type integrated circuits because of process complexity.

What is needed, therefore, are semiconductor device structures that integrate field effect transistors and bipolar junction transistors on a single substrate and methods for fabricating such hybrid semiconductor device structures.

### SUMMARY OF THE INVENTION

The present invention is directed to semiconductor device structures and fabrication methods that integrate non-planar bipolar junction transistors and field effect transistors on a common substrate. The device structures may comprise bipolar complementary metal-oxide-semiconductor (BiCMOS) device structures built using a silicon-on-insulator (SOI) substrate. The bipolar junction transistors and the CMOS field effect transistors of these BiCMOS device strictures are fabricated as non-planar devices on adjacent electrically-isolated semiconductor bodies fashioned from the semiconductor material of an SOI layer of the SOI substrate.

In accordance with an aspect of the present invention, a semiconductor device structure comprises first and second semiconductor bodies each having a top surface and first and second sidewalls extending from the top surface toward the insulating layer. The first semiconductor body includes a source region, a drain region, and a channel region between the source region and the drain region. A gate electrode overlaps the channel region of the first semiconductor body. First and second regions are disposed on at least one of the top surface, the first sidewall, and the second sidewall of the second semiconductor body with the first region at least partially positioned between the second region and the second semiconductor body. The first and second regions have different conductivity types. The first and second regions are coextensive along a first junction adjacent to the at least one of the top surface, the first sidewall, and the second sidewall of the second semiconductor body.

In accordance with another aspect of the present invention, a method is provided for fabricating a semiconductor device structure. The method comprises forming electrically-isolated first and second semiconductor bodies each having a top surface and first and second sidewalls extending from the top surface toward the insulating layer. Source and drain regions are formed in the first semiconductor body and a gate electrode is formed that overlaps a channel region of the first semiconductor body positioned between the source and drain regions. A first region of a first semiconductor material having a first conductivity type is formed that is disposed on at least one of the top surface, the first sidewall, or the second sidewall of the second semiconductor body. The method further comprises forming a second region of a second semiconductor material having a second conductivity type that is at least partially coextensive with the first region to define a first junction.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIGS. 1-17 are diagrammatic views of a portion of a substrate at successive fabrication stages of a processing method in accordance with an embodiment of the present invention in which A represents a cross-sectional view and B is a corresponding cross-sectional view taken generally along lines B-B in A.

FIG. 18 is an isometric view of the substrate portion of FIG. 17 after contacts are formed to the emitter, base, and collector regions.

FIG. 19 is a cross-sectional view taken generally along line 19-19 in FIG. 18.

FIG. 19A is a cross-sectional view taken generally along line 19A-19A in FIG. 19.

### DETAILED DESCRIPTION

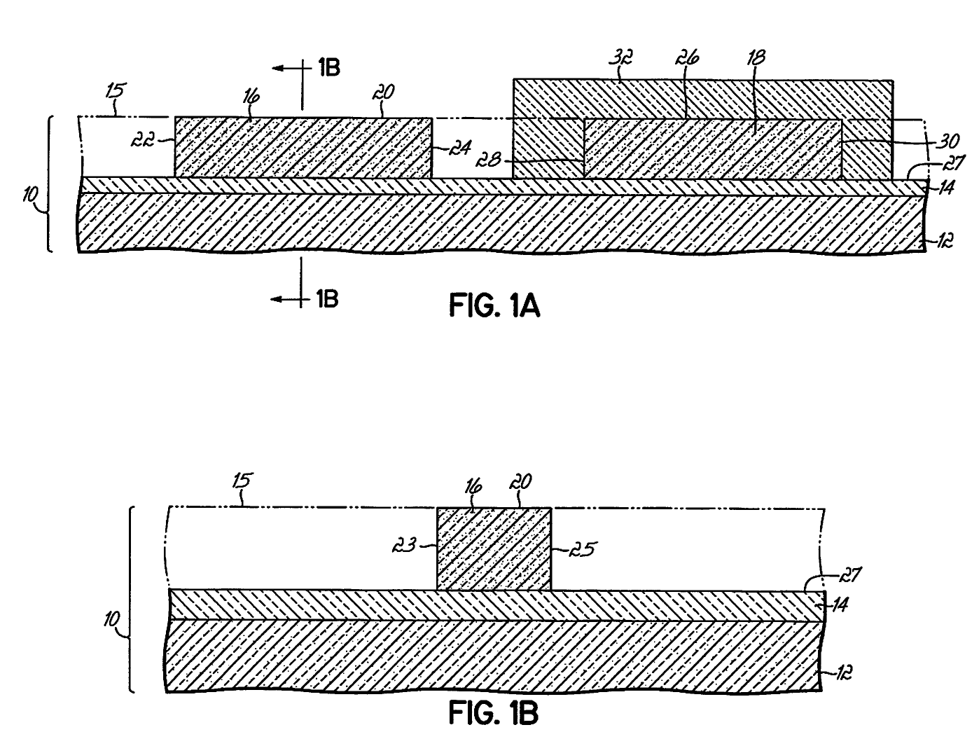

With reference to FIGS. 1A and 1B, an SOI wafer 10 comprises a handle substrate 12, a buried insulating layer 14, and a semiconductor or SOI layer 15 patterned by a conventional lithography and subtractive etching process to define a plurality of semiconductor mesas or fin structures, of which fin structures 16, 18 are representative and visible in FIGS. 1A, 1B. The fin structures 16, 18 are physically separated from the handle substrate 12 by the intervening buried insulating layer 14. The handle substrate 12 may be single crystal or monocrystalline silicon, although the invention is not so limited. The fin structures 16, 18, and the SOI layer 15 from which the fin structures 16, 18 originate, are considerably thinner than the handle substrate 12 and may be advantageously composed of single crystal or monocrystalline silicon, germanium, or silicon germanium. In one embodiment, the SOI layer 15 may be strained. The buried insulating layer 14 electrically isolates the semiconductor material comprising the fin structures 16, 18 from the handle substrate 12 and the fin structures 16, 18 from each other. The buried insulating layer 14 may consist of a buried silicon dioxide (BOX) layer. SOI wafer 10 may be fabricated by any suitable conventional technique, such as a wafer bonding technique or a separation by implantation of oxygen (SIMOX) technique, familiar to a person having ordinary skill in the art.

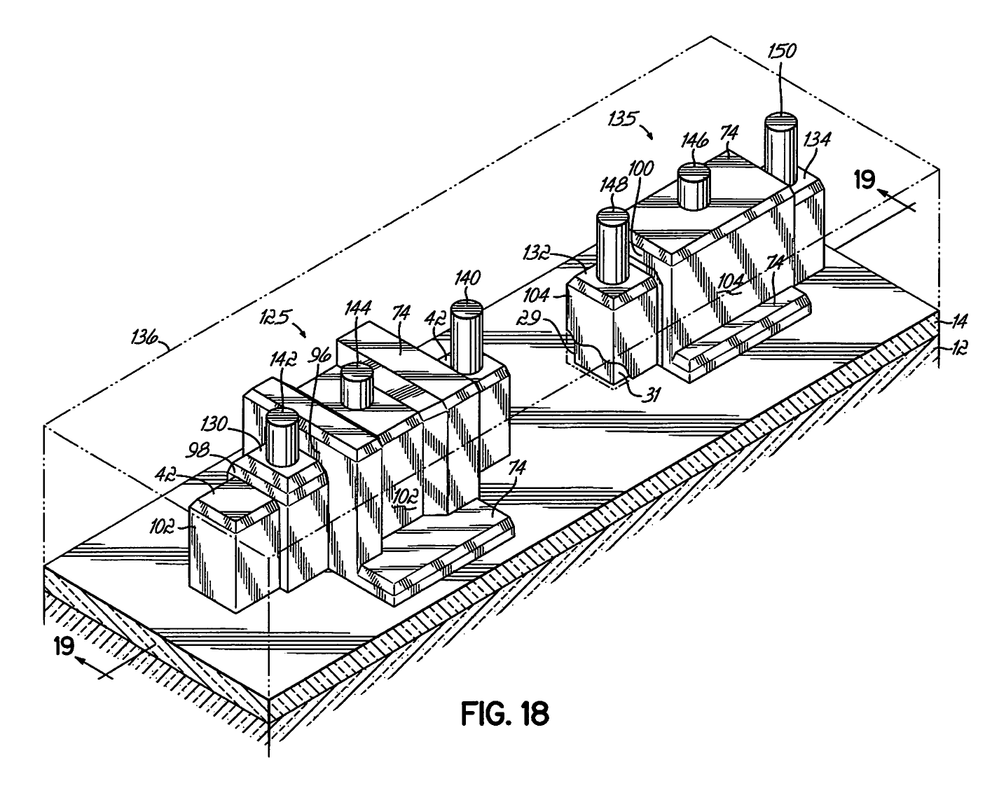

The fin structures 16, 18 each represent a thin upright body of the semiconductor material originally constituting the SOI layer 15 and, thus, have a “fin” type shape. Fin structure 16 has a top surface 20 and a plurality of sidewalls, of which laterally opposite sidewalls 22, 24 are visible in FIG. 1A and laterally opposite sidewalls 23, 25 are visible in FIG. 1B. Each of the sidewalls 22, 23, 24, 25 extends from the top surface 20 toward a top surface 27 of the buried insulating layer 14. Similarly, fin structure 18 has a top surface 26 and a plurality of sidewalls, of which laterally opposite sidewalls 28, 30 are visible in FIG. 1A and laterally opposite sidewalls 29, 31 are visible in FIG. 18. Each of the sidewalls 28, 29, 30, 31 extends from the top surface 26 toward the top surface 27 of the buried insulating layer 14.

The height of fin structure 16, which is measured as the perpendicular distance between the top surfaces 20, 27, and the height of fin structure 18, which is measured as the perpendicular distance between the top surfaces 26, 27, typically range from about 30 nm to about 300 nm. The width of each of the fin structures 16, 18 typically ranges from about 10 nm to about 100 nm. Optionally and before the formation of fin structures 16, 18, the SOI layer 15 may be thickened by epitaxial growth of the constituent semiconductor material (e.g., silicon).

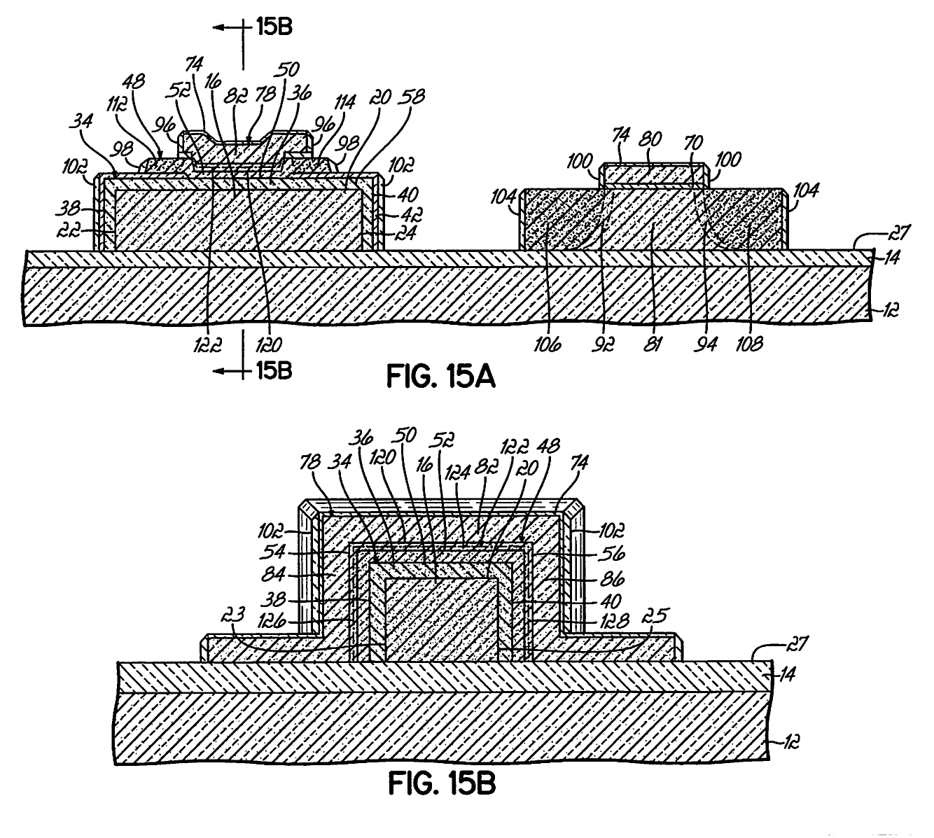

Fin structure 18 is protected by a patterned block mask 32 while the bipolar junction transistors are formed, of which bipolar junction transistor 125 (FIGS. 15A, 15B) formed in fin structure 16 is representative. Block mask 32 covers the sidewalls 28, 29, 30, 31 and top surface 26 of fin structure 18. Block mask 32 may be composed of a diamond film deposited by a chemical vapor deposition (CVD) process or any other suitable hard mask material, such as germanium, that may be selectively removed without damaging the masked semiconductor material of fin structure 18.

Fin structure 16 is uniformly doped by ion implantation with a dose of an appropriate impurity. A subsequent thermal anneal may be required to electrically activate and/or distribute the implanted impurity in the semiconductor material of the fin structure 16. The impurity implanted to dope the semiconductor material of the fin structure 16 may have, for example, an n-conductivity type (e.g., arsenic). Generally, the resultant dopant concentration in the fin structure 16 may range from about 1×10¹⁸ cm⁻³ to about 1×10²⁰ cm⁻³. Other alternative impurity-introduction techniques, such as gas phase doping and solid source doping, may be employed to dope the semiconductor material of the fin structure 16.

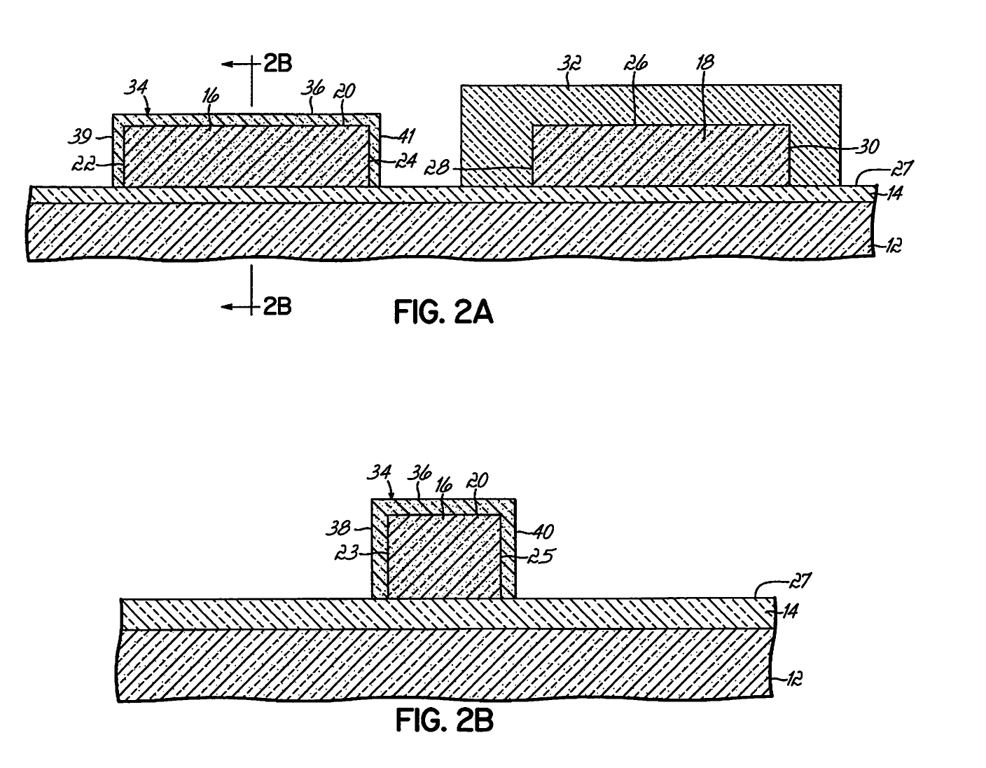

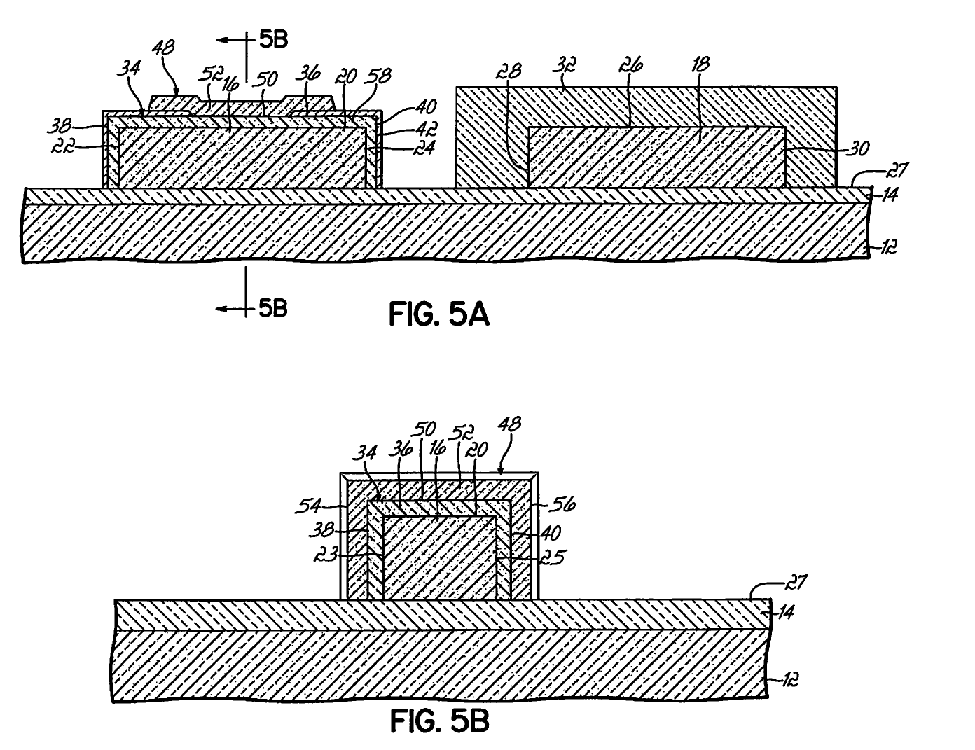

With reference to FIGS. 2A and 2B in which like reference numerals refer to like features in FIGS. 1A and 1B and at a subsequent fabrication stage, a collector region 34 of bipolar junction transistor 125 (FIGS. 15A, 15B) is defined by forming a semiconductor layer on the fin structure 16. The semiconductor layer forming the collector region 34 may be formed by an epitaxial process, such as a CVD process using a silicon source gas (e.g., silane). The semiconductor material constituting the collector region 34 is doped in situ during deposition with an impurity having the same conductivity type as the semiconductor material of fin structure 16 but at a lower concentration. The doping concentration in the constituent semiconductor material of the collector region 34 is selected to provide a desired collector junction doping profile according to design parameters for the bipolar junction transistor 125 (FIGS. 15A, 15B). Generally, the dopant concentration of the collector region 34 near the fin structure 16 may range from about 1×10¹⁸ cm⁻³ to about 1×10²⁰ cm⁻³ to ensure relatively low series resistance with the fin structure 16, and the dopant concentration of the collector region 34 near the base region 48 (FIGS. 5A, 5B) may range from about 1×10¹⁷ cm⁻³ to about 1×10¹⁸ cm⁻³ to provide a low-leakage collector-base junction 50 (FIGS. 5A, 5B).

The collector region 34 comprises a top segment 36 and sidewall segments 38, 40 (FIG. 2B) that are joined by the top segment 36 to define a continuous structure. The top segment 36 of the collector region 34 is coextensive (i.e., shares a border) with the top surface 20 of fin structure 16 and the sidewall segments 38, 40 are respectively coextensive with the sidewalls 23, 25 of fin structure 16. The sidewall segments 38, 40 extend from the top segment 36 along the sidewalls 23, 25 toward the top surface 27 of the buried insulating layer 14. The collector region 34 also includes segments 39, 41 (FIG. 2A) that extend from the top segment 36 along the sidewalls 22, 24 toward the top surface 27 of the buried insulating layer 14.

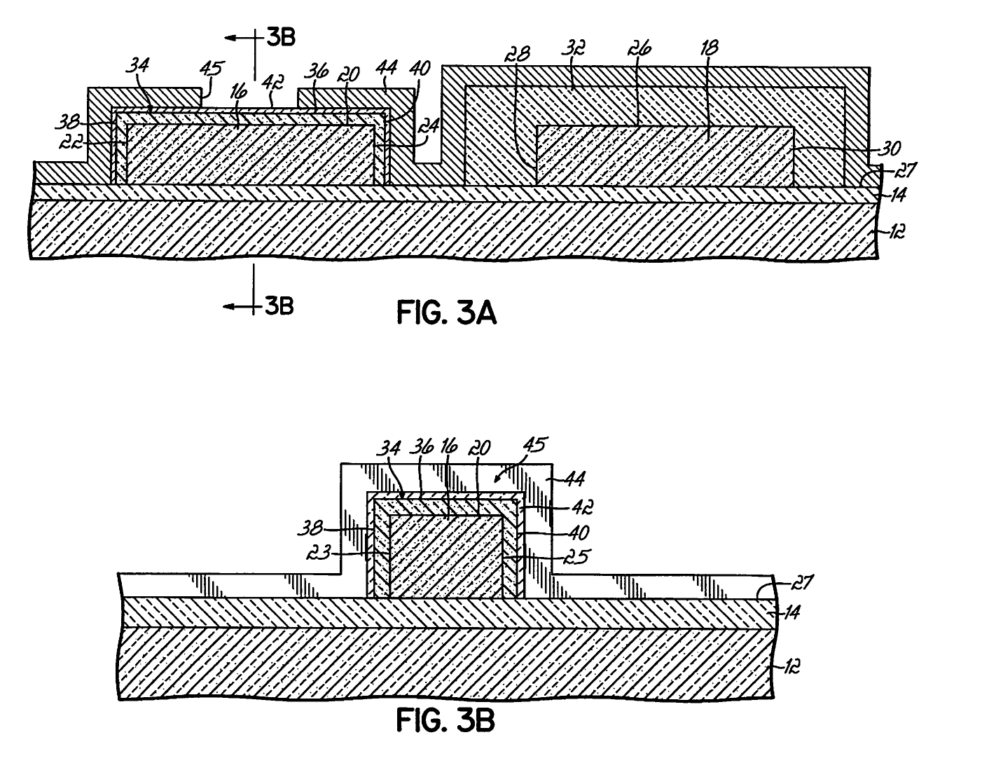

With reference to FIGS. 3A and 3B in which like reference numerals refer to like features in FIGS. 2A and 2B and at a subsequent fabrication stage, a thin layer 42 of a dielectric is formed on the collector region 34 to cap the constituent semiconductor material. The dielectric layer 42 may comprise, for example, an oxide grown on the semiconductor material constituting the collector region 34 using a conventional wet or dry thermal oxidation process. The dielectric layer 42 covers the top segment 36 and sidewall segments 38, 40 of collector region 34, which is disposed between the fin structure 16 and the dielectric layer 42.

The dielectric layer 42 is patterned by a conventional lithography and subtractive etching process. The lithography process applies a radiation-sensitive resist 44 on dielectric layer 42, exposes the resist 44 to a pattern of radiation (e.g., light, x-rays, or an electron beam), and develops the latent transferred pattern in the exposed resist 44 to define a representative opening 45 that extends across the top surface 20 and along the sidewalls 23, 25 of fin structure 16. Thus, opening 45 extends across the top segment 36 and along the sidewall segments 38, 40 of the collector region 34.

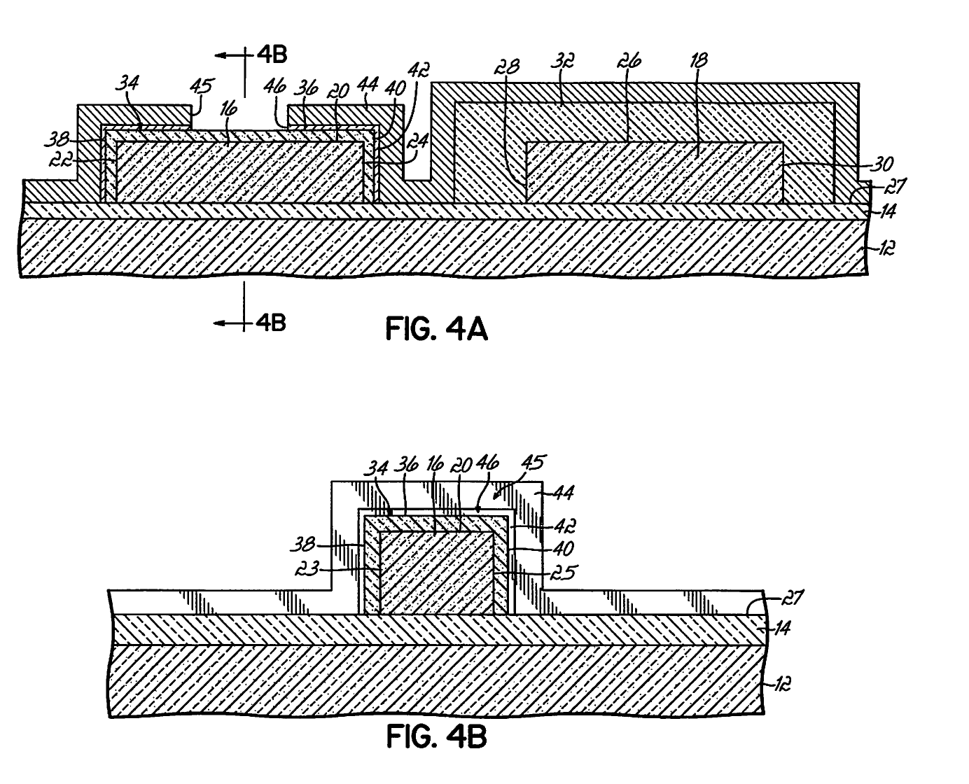

With reference to FIGS. 4A and 4B in which like reference numerals refer to like features in FIGS. 3A and 3B and at a subsequent fabrication stage, the subtractive etching process, which may be an anisotropic dry etch process like reactive ion etching (RIE) or plasma etching, transfers the pattern in the resist 44 to the dielectric layer 42. The subtractive etching process defines a base opening 46 to the collector region 34 by partially removing unmasked areas of dielectric layer 42 registered with the opening 45 in the patterned resist 44, which serves as an etch mask. The subtractive etching process, which relies on an etchant chemistry that removes the constituent material of the dielectric layer 42 selective to the semiconductor material constituting collector region 34, stops on the constituent semiconductor material of collector region 34. The dielectric layer 42 includes peripheral regions that overlap with the buried insulating layer 14 peripherally of the fin structure 16, as evident in FIG. 4A.

Base opening 46 extends across the top surface 20 and along the sidewalls 23, 25 of the fin structure 16. Thus, the base opening 46 extends across the top segment 36 and along the sidewall segments 38, 40 of the collector region 34. The top segment 36 and sidewall segments 38, 40 of collector region 34 are exposed through the base opening 46 and are free of coverage by the dielectric layer 42, which has edges that peripherally bound the base opening 46.

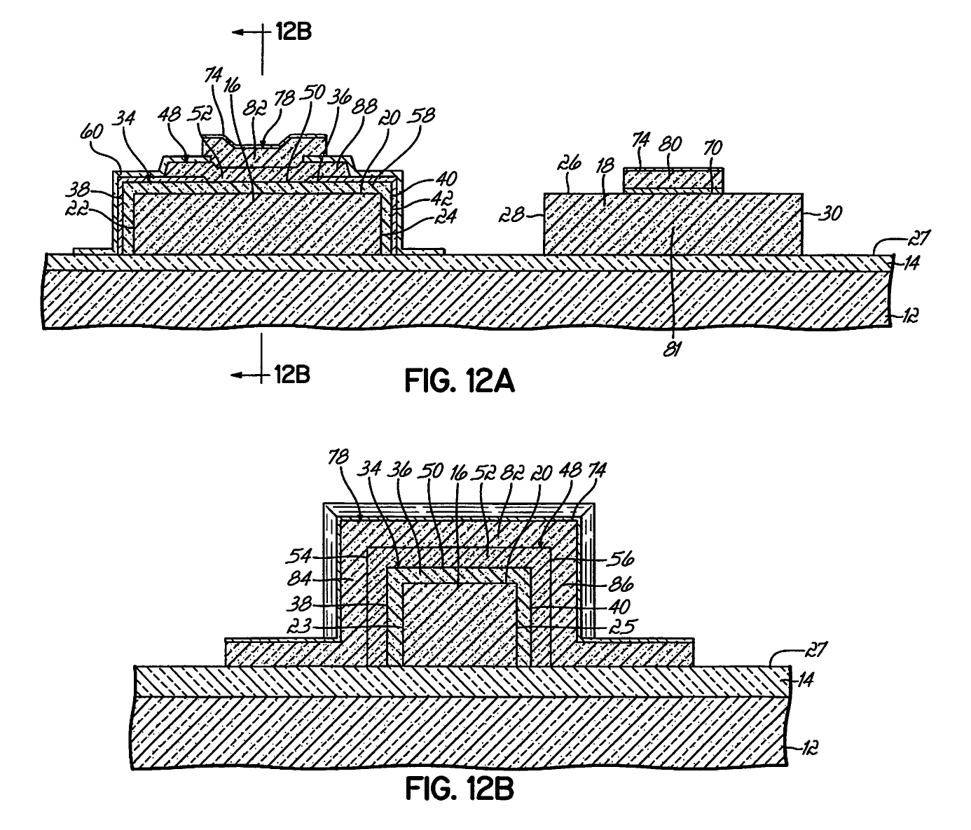

With reference to FIGS. 5A and 5B in which like reference numerals refer to like features in FIGS. 4A and 4B and at a subsequent fabrication stage, the patterned resist 44 (FIGS. 4A, 4B) is removed using a conventional solvent stripping process or by ashing. A base region 48 of the bipolar junction transistor 125 (FIGS. 15A, 15B) is then formed by a selective epitaxial growth process with in situ impurity doping that fills the base opening 46 with an impurity-doped semiconductor material, such as silicon or a silicon-containing semiconductor material. For example, the dopant concentration of the base region 48 may be graded from about 1×10¹⁷ cm⁻³ near the collector region 34 to about 5×10¹⁸ cm⁻³ near an emitter region 78 (FIGS. 12A, 12B). The collector-base junction 50 is defined across the boundary shared by the coextensive or overlapping portions of the collector region 34 and base region 48. The impurity implanted to dope the semiconductor material of the base region 48 may have, for example, a p-conductivity type (e.g., boron).

The semiconductor material forming the base region 48 is doped with an impurity having an opposite conductivity type to collector region 34. The semiconductor material of the collector region 34 may be characterized by an n-type conductivity that exhibits a higher concentration of electrons than holes so that electrons are majority carriers and dominate the electrical conductivity of the material. The semiconductor material of the base region 48 may be characterized by a p-type conductivity that exhibits a higher concentration of holes than electrons so that holes are majority carriers and dominate the electrical conductivity of the material. Alternatively, the conductivity types for the semiconductor material of collector and base regions 34, 48 may be reversed.

In one embodiment, the silicon-containing semiconductor material constituting the base region 48 may be an impurity doped silicon-germanium alloy (SiₓGe₁₋ₓ) in which the silicon atomic concentration ranges from about 65% to about 90% and the germanium atomic concentration ranges from about 10% to about 35%. The SiₓGe₁₋ₓ may be deposited using any conventional epitaxial growth method capable of growing a SiGe alloy with in situ doping that is substantially free from defects, i.e., misfit and threading dislocations. An illustrative example of such an epitaxial growth process capable of growing substantially defect free films is a low-pressure chemical vapor deposition (LPCVD) process using silane (SiH₄) and germane (GeH₄) as reactant gasses and conducted at a relatively low process temperature.

Base region 48 is physically separated from the fin structure 16 by the collector region 34. Base region 48 has a top segment 52 that is coextensive with the top segment 36 of collector region 34 and sidewall segments 54, 56 that are respectively coextensive with the sidewall segments 38, 40 of collector region 34. The sidewall segments 54, 56 are joined by the top segment 52. The base region 48 extends across the top surface 20 and along the sidewalls 23, 25 of the fin structure 16. Thus, the top segment 52 and sidewalls segments 54, 56 of the base region 48 contact the top segment 36 and sidewall segments 38, 40 of the collector region 34, respectively. The collector-base junction 50 is defined across the coextensive, contacting surface areas of the doped semiconductor material of the collector region 34 having one conductivity type and the doped semiconductor material of the base region 48 having the opposite conductivity type.

The periphery of the base region 48, which is designated by the lateral extent of the base opening 46 and the process forming the base region 48, is selected such that a contact pad 58 of the collector region 34 extends laterally of the periphery of the base region 48. The contact pad 58 is not overlapped by the base region 48 and, thus, does not participate in forming the collector-base junction 50. The contact pad 58 is employed to electrically contact the collector region 34, as described below.

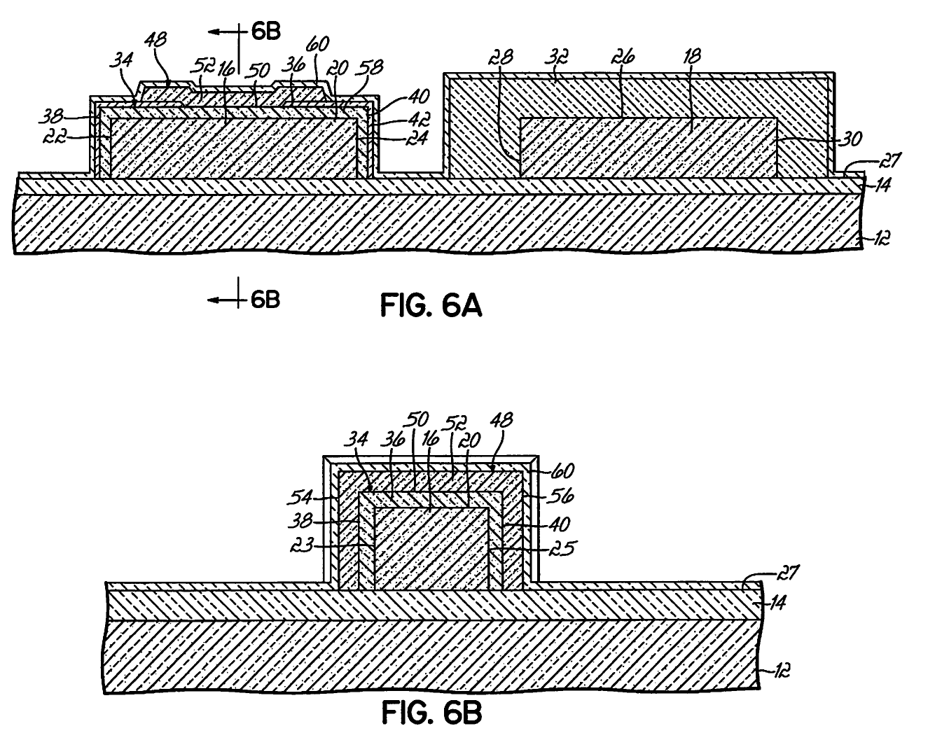

With reference to FIGS. 6A and 6B in which like reference numerals refer to like features in FIGS. 5A and 5B and at a subsequent fabrication stage, a layer 60 of a dielectric is conformally deposited across the fin structure 16. The dielectric in layer 60 may be silicon nitride (Si₃N₄) formed by a thermal CVD process like low pressure chemical vapor deposition (LPCVD) or by a plasma-assisted CVD process. The dielectric layer 60 extends across the top surface 20 and along the sidewalls 22, 23, 24, 25 of the fin structure 16.

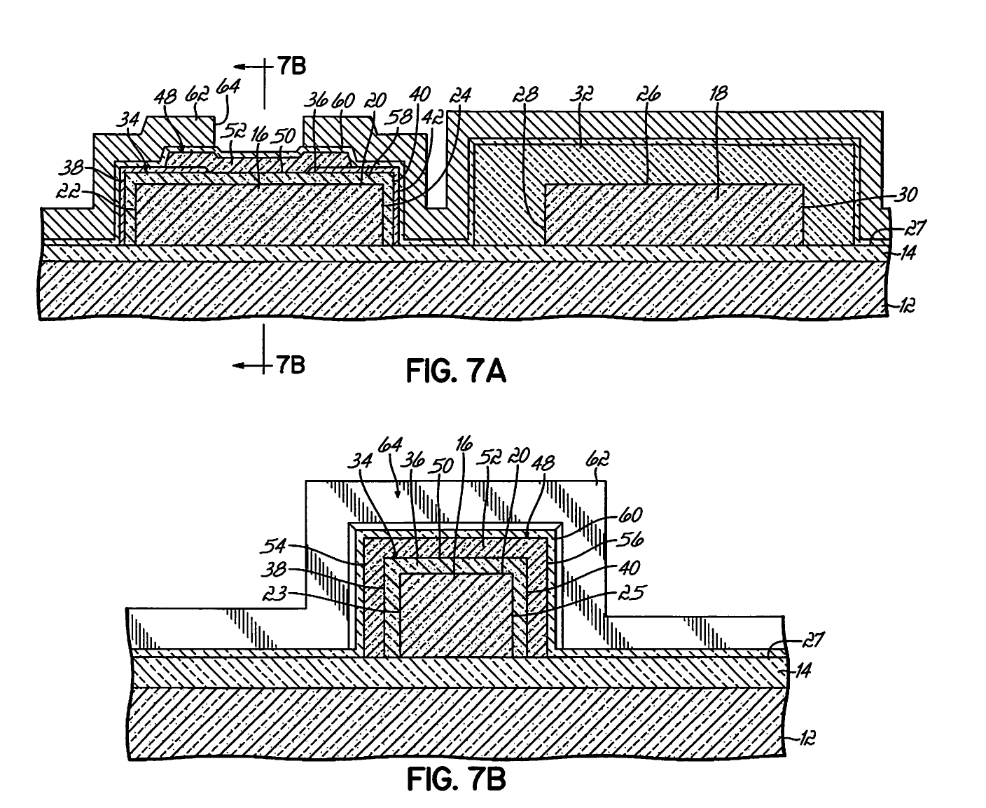

With reference to FIGS. 7A and 7B in which like reference numerals refer to like features in FIGS. 6A and 6B and at a subsequent fabrication stage, the dielectric layer 60 is patterned by a conventional lithography and subtractive etching process. The lithography process applies a radiation-sensitive resist 62 on dielectric layer 60, exposes the resist 62 to a pattern of radiation, and develops the latent transferred pattern in the exposed resist 62 to define an opening 64. The opening 64 extends across the top surface 20 and along the sidewalls 23, 25 of the fin structure 16.

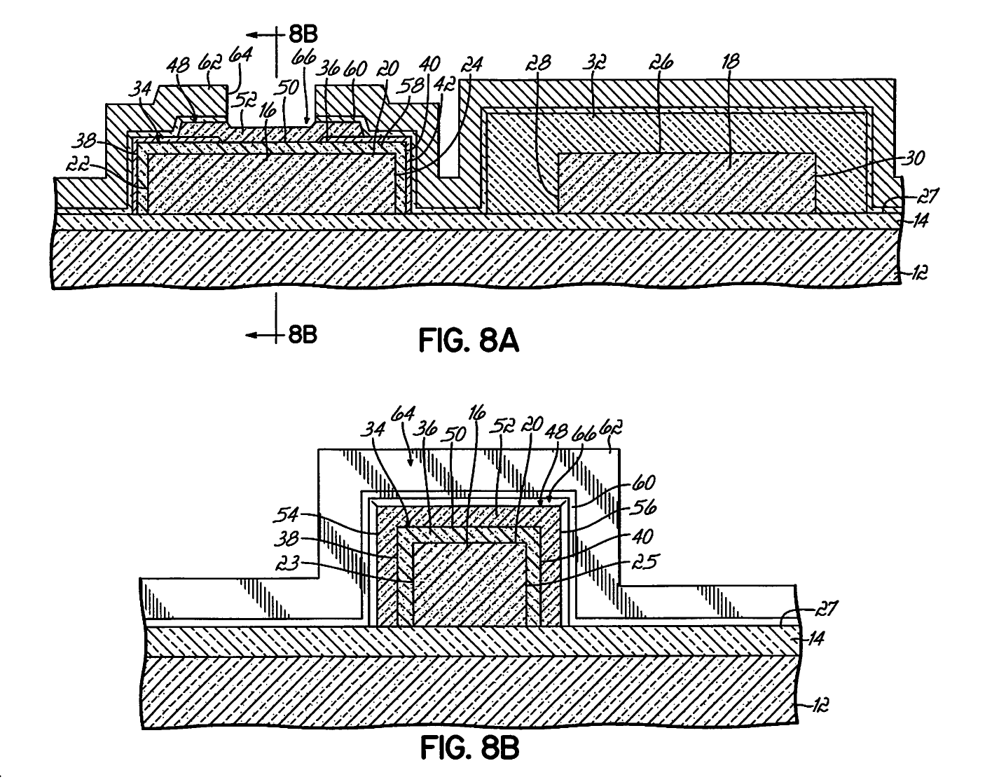

With reference to FIGS. 8A and 8B in which like reference numerals refer to like features in FIGS. 7A and 7B and at a subsequent fabrication stage, an emitter area 66 is defined across the top segment 52 and sidewall segments 54, 56 of the base region 48 by transferring the pattern in the resist 62 to the dielectric layer 60 using an anisotropic dry etch process like RIE or plasma etching. The dry etching process defines the emitter area 66 by removing an unmasked portion of dielectric layer 60 registered with the opening 64 in patterned resist 62, which operates as an etch mask. The dry etching process, which has an etchant chemistry that removes the constituent material of the dielectric layer 60 selective to the semiconductor material of the base region 48, stops on the constituent semiconductor material of base region 48. The top segment 52 and sidewall segments 54, 56 of base region 48 are exposed across the emitter area 66. The resist 62 (FIGS. 7A, 7B) is subsequently removed using a conventional solvent stripping process or by ashing. Dielectric layer 60 is patterned using a conventional lithography and etching process.

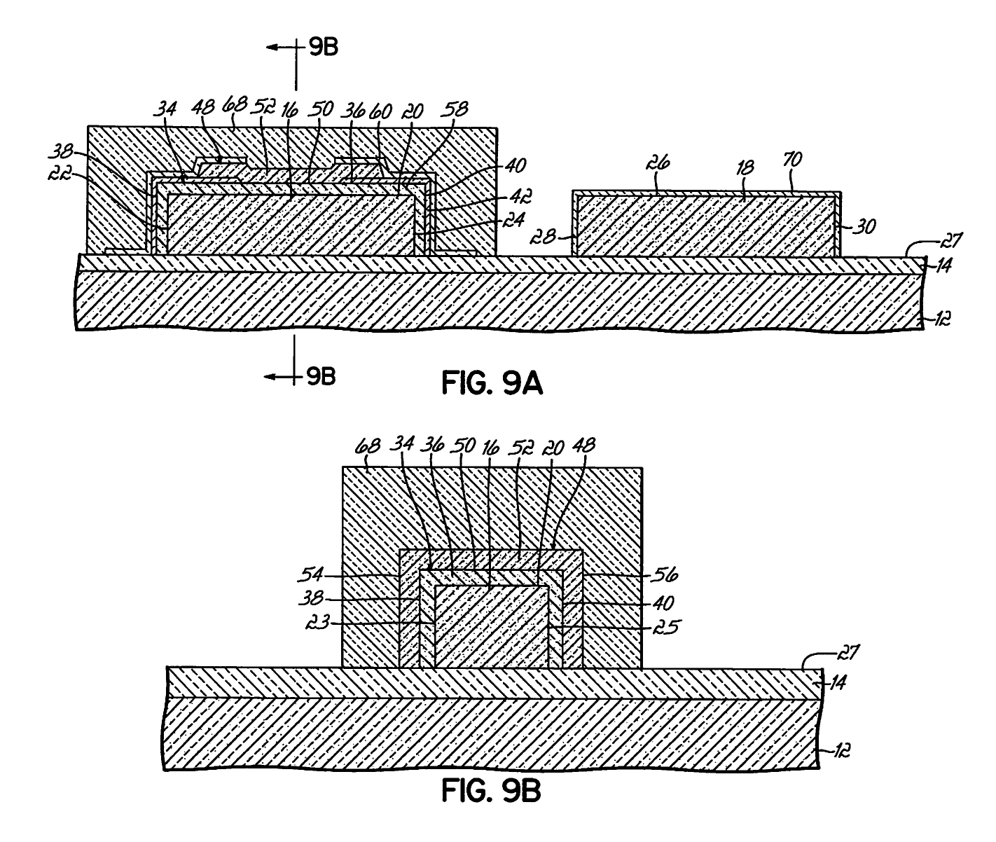

With reference to FIGS. 9A and 9B in which like reference numerals refer to like features in FIGS. 8A and 8B and at a subsequent fabrication stage, block mask 32 (FIGS. 1A, 1B) is removed to expose the top surface 26 and sidewalls 28, 29, 30, 31 of fin structure 18. A block mask 68, which is similar to block mask 32, is applied that covers the partially completed bipolar junction transistor 125 (FIGS. 15A, 15B) and fin structure 16.

A gate dielectric 70, which may comprise a dielectric or insulating material like silicon dioxide, silicon oxynitride, a high-k dielectric, or any other suitable dielectric or combinations thereof, is then formed on the fin structure 18. The dielectric material constituting gate dielectric 70 may be between about 1 nm and about 10 nm thick, and may be formed by thermal reaction of the exterior semiconductor material of the fin structure 18 with a reactant, CVD, a physical vapor deposition (PVD) technique, or a combination thereof. Gate dielectric 70 extends across the top surface 26 and sidewalls 28, 29, 30, 31 of fin structure 18 toward the top surface 27 of the buried insulating layer 14.

Before the gate dielectric 70 is formed, fin structure 18 may be ion implanted for purposes of channel doping. If the fin structure 18 is relatively narrow (i.e., less than about 10 nm to 20 nm), then the subsequently-formed FinFET operates in a fully depleted mode, which eliminates the need for channel doping because the threshold voltage is established by the work function of the conductor of gate electrode 80 (FIGS. 12A, 12B). Alternatively, source/drain halo regions (not shown) may be subsequently formed to set the threshold voltage without the need for channel doping.

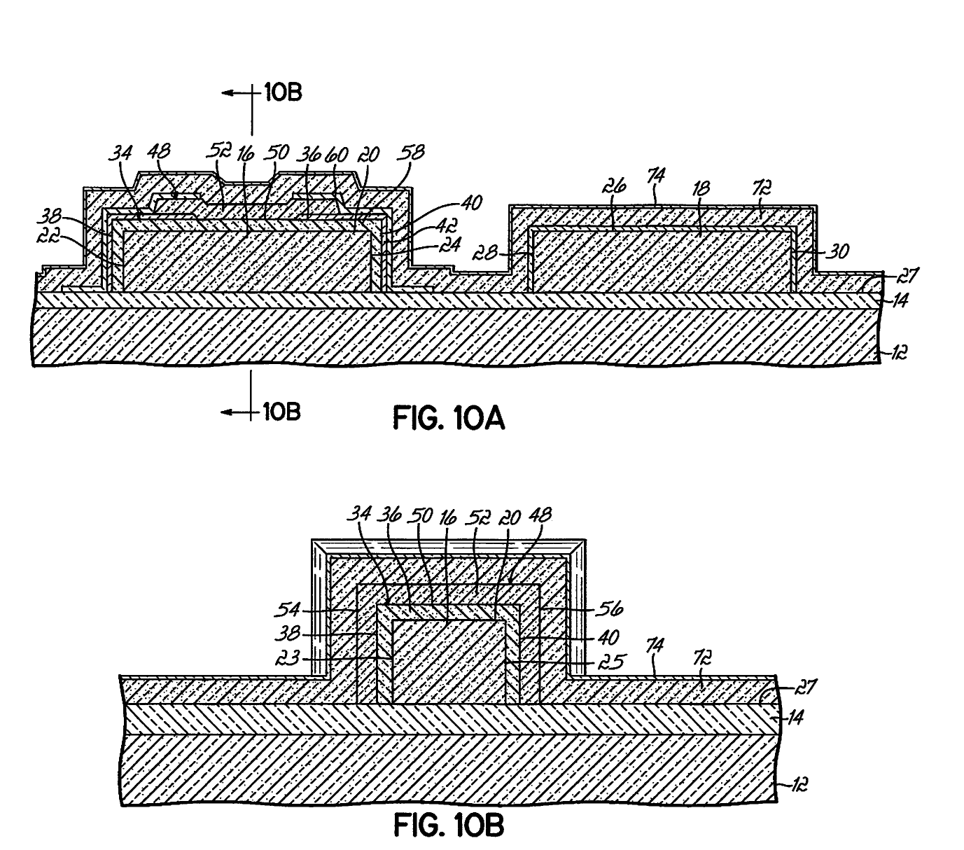

With reference to FIGS. 10A and 10B in which like reference numerals refer to like features in FIGS. 9A and 9B and at a subsequent fabrication stage, the block mask 68 (FIGS. 9A, 9B) is removed. A layer 72 of a semiconductor material is formed across the top surface 20 and along the sidewalls 22, 23, 24, 25 of fin structure 16 and also across the top surface 26 and along the sidewalls 28, 29, 30, 31 of fin structure 18. The semiconductor layer 72 may be composed of polycrystalline silicon (i.e., polysilicon) deposited by a CVD process. Semiconductor layer 72 is doped during deposition with a concentration of an impurity having the same conductivity type as the semiconductor material of collector region 34 but the opposite conductivity type in comparison with the semiconductor material constituting base region 48. The semiconductor layer 72 is coextensive with the base region 48 across the emitter area 66, which is bounded peripherally by the encircling edges of the dielectric layer 60. A protective cap layer 74, which may comprise an oxide layer deposited by a CVD process, is formed on the semiconductor layer 72.

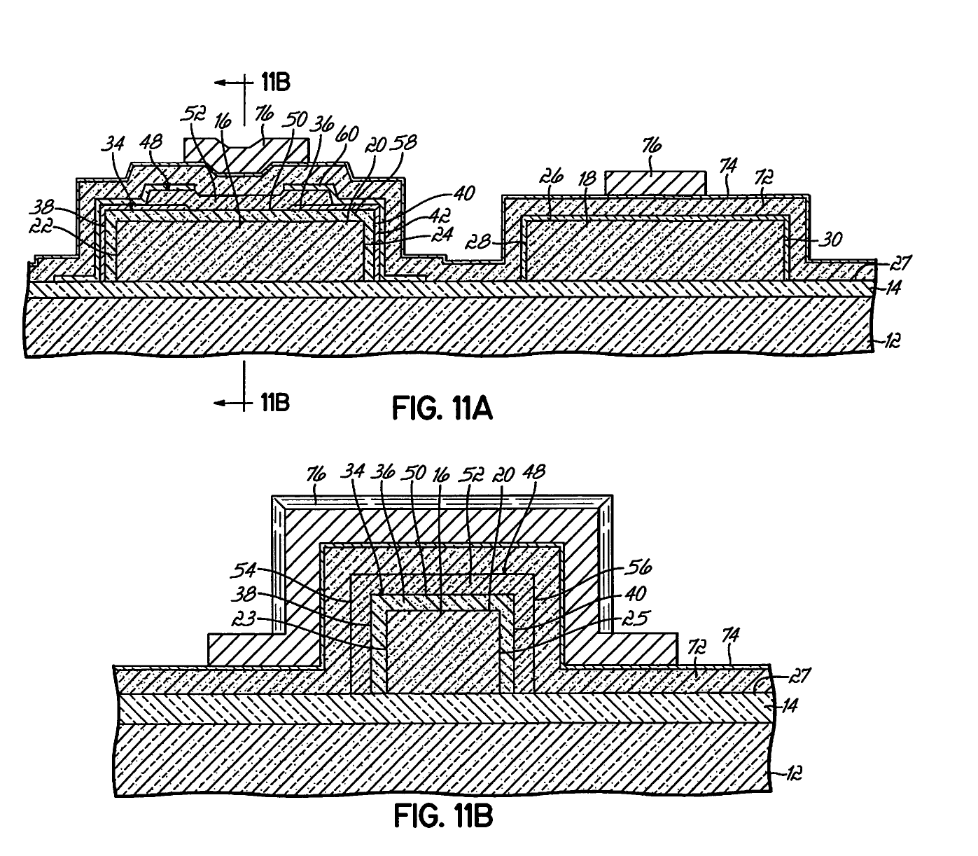

With reference to FIGS. 11A and 11B in which like reference numerals refer to like features in FIGS. 10A and 10B and at a subsequent fabrication stage, the semiconductor layer 72 and cap layer 74 are patterned by a conventional lithography and subtractive etching process. The lithography process applies a radiation-sensitive resist 76 on cap layer 74, exposes the resist 76 to a pattern of radiation, and develops the latent transferred pattern in the exposed resist 76 to define a residual strip or island of resist 76 covering a portion of the semiconductor layer 72 and cap layer 74 on fin structure 16 and another residual strip or island of resist 76 covering a portion of the semiconductor layer 72 and cap layer 74 on fin structure 18. One residual island of resist 76 extends across the top surface 20 and along the sidewalls 23, 25 of fin structure 16. The other residual island of resist 76 may extend across the top surface 26 and along the sidewalls 28, 30 of fin structure 18.

With reference to FIGS. 12A and 12B in which like reference numerals refer to like features in FIGS. 11A and 11B and at a subsequent fabrication stage, the subtractive etching process removes portions of the semiconductor layer 72 and cap layer 74 not masked by the residual island of resist 76 (FIGS. 11A, 11B). The portion of the semiconductor layer 72 on fin structure 16 that is masked by resist 76 during the subtractive etching process comprises an emitter region 78 of the bipolar junction transistor 125 (FIGS. 15A, 15B). The portion of the semiconductor layer 72 on fin structure 18 that is masked by resist 76 during the subtractive etching process comprises a gate electrode 80 of the field effect transistor 135 (FIGS. 15A, 15B) that is capped by a residual portion of cap layer 74. The subtractive etching process includes one or more anisotropic dry etch processes, such as RIE or plasma etching, that patterns the cap layer 74 using the resist 76 as an etch mask and then patterns the semiconductor layer 72 using the patterned cap layer 74 and resist 76 as an etch mask. The subtractive etching process, which may be conducted in a single etching step or multiple steps, stops on the dielectric layer 60 on fin structure 16 and gate dielectric 70 on fin structure 18. After the emitter region 78 and gate electrode 80 are defined, the resist 76 is removed using solvent stripping or ashing.

The emitter region 78, which has a top segment 82 and sidewall segments 84, 86 joined by the top segment 82, is physically separated from the collector region 34 by the base region 48. Top segment 82 is coextensive with the top segment 52 of base region 48. Sidewall segments 84, 86 are respectively coextensive with the sidewall segments 54, 56 of base region 48. The top segment 82 and sidewall segments 84, 86 of emitter region 78 extend adjacent to the top segment 20 and the sidewall segments 23, 25 of the fin structure 16. The lateral extent of the emitter region 78, which is designated by the lateral extent of the resist 76, is selected such that a contact pad 88 of the base region 48 is outside of the perimeter or periphery of the emitter region 78.

The gate electrode 80 has an alignment that intersects a central channel region 81 and overlaps the top surface 26 and the sidewalls 29, 31 of the fin structure 18 along the central channel region 81. As a consequence, the gate electrode 80 wraps around three sides of the fin structure 18. The gate electrode 80 is separated physically from the fin structure 18 by the intervening portions of the gate dielectric 70.

The deposition and patterning of semiconductor layer 72 may be applied to exclusively form the emitter region 78 if the conductivity type of the gate electrode 80 is not identical to the conductivity type of the emitter region 78. To that end, fin structure 18 may be masked with a photoresist block mask during the deposition and patterning of semiconductor layer 72 to form emitter region 78 and, then, a separate layer (not shown) doped with the opposite conductivity type may be deposited and patterned to form gate electrode 80 with another block mask covering the fin structure 16.

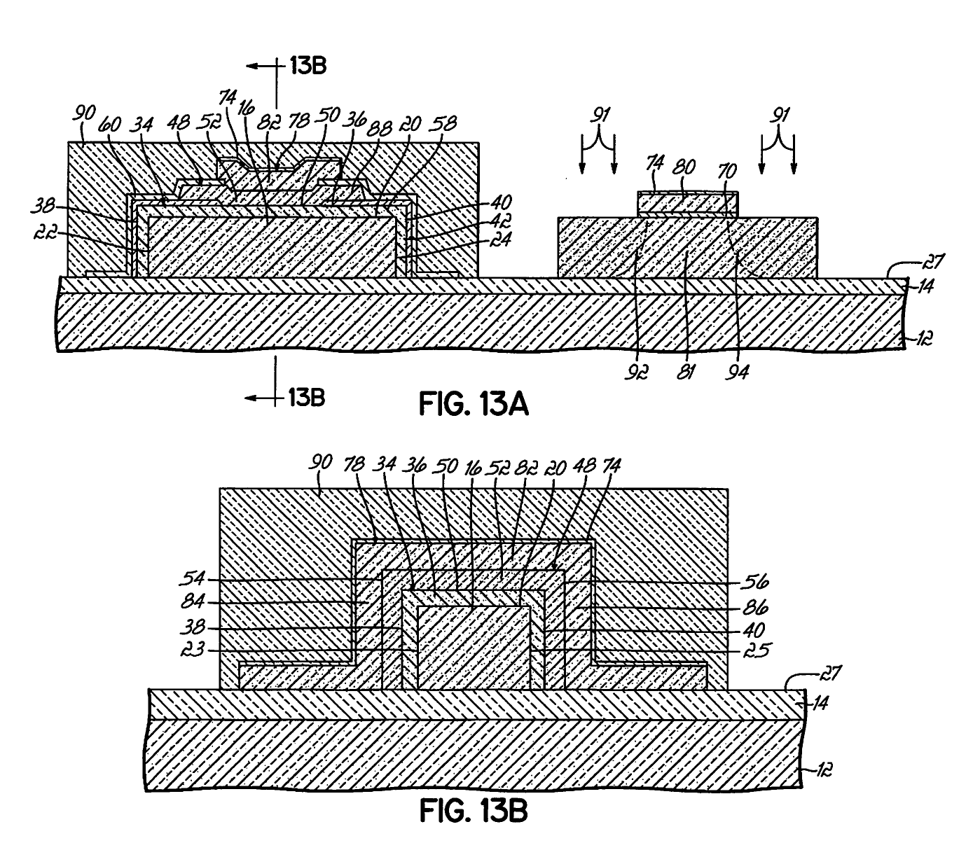

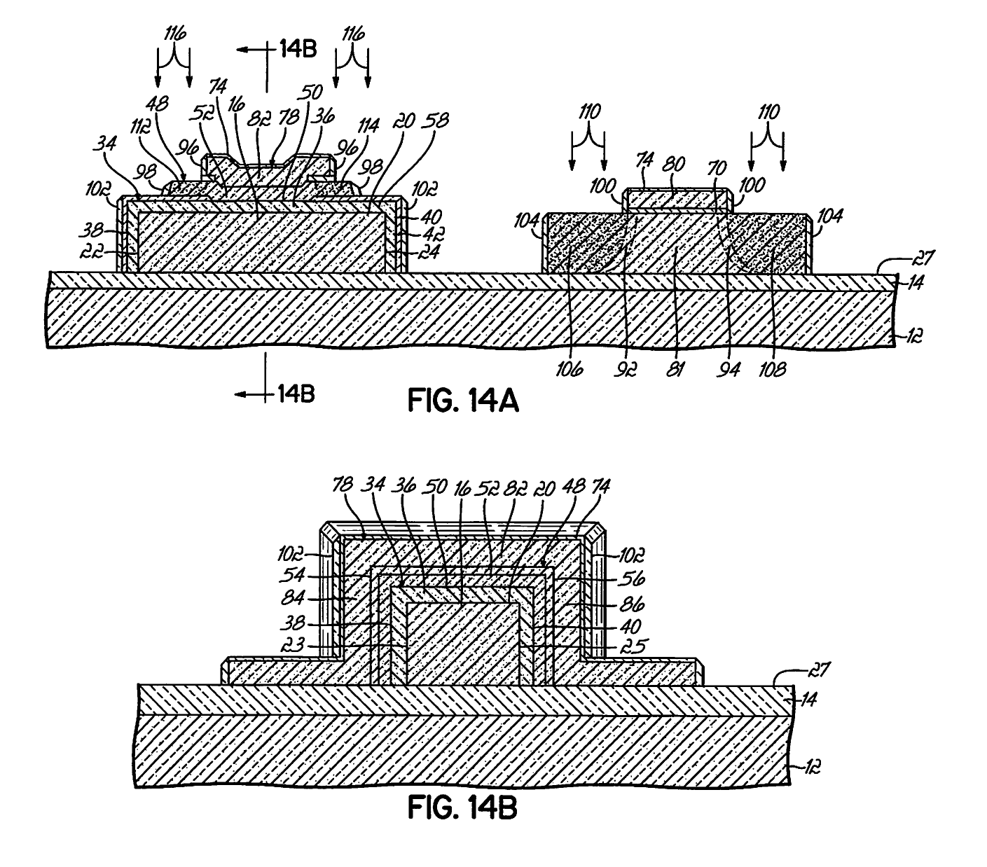

With reference to FIGS. 13A and 13B in which like reference numerals refer to like features in FIGS. 12A and 12B and at a subsequent fabrication stage, fin structure 16 is masked with a photoresist block mask 90. The semiconductor material of fin structure 18 is implanted with ions 91 of a dopant to define shallow source/drain extensions 92, 94 at opposing sides of the gate electrode 80. The extension implant may be angled to penetrate laterally beneath the gate dielectric 70. The semiconductor material of the fin structure 18 is also ion implanted with a dopant to form optional halo regions (not shown) that are located underneath and laterally adjacent to the shallow source/drain extensions 92, 94. The optional halo regions are of the opposite conductivity or doping polarity (either N-type or P-type) from the shallow source/drain extensions 92, 94, which assists in controlling source to drain leakage currents between source/drain regions 106, 108 (FIGS. 14A, 14B) when the field effect transistor 135 (FIGS. 15A, 15B) is quiescent or idle (i.e., switched to an “off” state). The ion implantations forming the shallow source/drain extensions 92, 94 and the optional halo regions are performed utilizing conventional ion implantation equipment, techniques, and conditions, such as dose, ion species, and ion kinetic energy, familiar to a person having ordinary skill in the art.

With reference to FIGS. 14A and 14B in which like reference numerals refer to like features in FIGS. 13A and 13B and at a subsequent fabrication stage, block mask 90 is removed using a conventional solvent stripping process or by ashing. A conventional film deposition and anisotropic etching process is used to form insulating spacers 96 on the peripheral edges of the emitter region 78, insulating spacers 98 on the peripheral edges of the base region 48, and insulating spacers 100 on the peripheral edges of the gate electrode 80. Dielectric layer 60, which may be composed of the same material as the film (e.g., nitride) deposited to form the spacers, is also anisotropically etched during spacer formation. Insulating spacers 102 are also formed on the vertical surfaces flanking the fin structure 16 and insulating spacers 104 are also formed on the vertical surfaces flanking the fin structure 18 as an artifact of the process forming spacers 96, 98, 100.

The anisotropic etching process removes portions of the dielectric layer 60 to expose the peripheral contact pad 88 of the base region 48. The contact pad 88 is not overlapped by the emitter region 78 and, thus, does not participate in forming an emitter-base junction 122 (FIGS. 15A, 15B). The contact pad 88 is used to electrically contact the base region 48, as described below.

Source/drain regions 106, 108, which flank the channel region 81, are then formed by, for example, an ion implantation technique that introduces ions 110 of a suitable n-type or p-type dopant and with a suitable dose and low kinetic energy into end regions of the fin structure 18 flanking the gate electrode 80. The gate electrode 80, the portion of cap layer 74 on gate electrode 80, and spacers 100 operate as a self-aligned mask for the ion implantation. Base extensions 112, 114, which flank the base region 48, are also formed by, for example, an ion implantation technique that introduces ions 116 of a suitable n-type or p-type dopant and with a suitable dose and low kinetic energy into regions of the fin structure 16 flanking the base region 48.

The ion implantations forming the source/drain regions 106, 108 and the base extensions 112, 114 are performed utilizing conventional ion implantation equipment, techniques, and conditions, such as dose, ion species, and ion kinetic energy, familiar to a person having ordinary skill in the art.

Additional block masks (not shown) may be used to implant ions of different conductivity types into fin structures (not shown), of which fin structure 18 is representative, to form shallow source/drain regions 106, 108, source/drain extensions 92, 94, and optional halo regions of appropriate conductivity type to make, for example, p-channel field effect transistors and n-channel field effect transistors required for complementary metal-oxide-semiconductor (CMOS) device structures.

With reference to FIGS. 15A and 15B in which like reference numerals refer to like features in FIGS. 14A and 14B and at a subsequent fabrication stage, the SOI wafer 10 is annealed at a temperature and for a time that promotes impurity diffusion from the doped semiconductor material of the emitter region 78 into the base region 48 across the emitter region 78. The thermal anneal may be performed in either a vacuum or inert environment, where an inert environment may comprise, for example, a non-reactive atmosphere of helium (He), argon (Ar), or nitrogen (N₂), and at a substrate temperature in the range of 950 C.° to 1100° C. The volume of semiconductor material of the base region 48 receiving the diffused impurity is doped with a net impurity concentration that is graded across a zone 120 from one conductivity type (i.e., n-type) near the emitter region 78 to the opposite conductivity type (i.e., p-type) of the base region 48. An emitter-base junction 122 is defined by the locus of points or transition between conductivity types in the graded zone 120 for which the net doping concentration is null or zero and generally by the overlap between coextensive portions of the emitter region 78 and the base region 48. The bulk of the emitter region 78 may have a dopant concentration of about 5×10¹⁹ cm⁻³ to about 5×10²⁰ cm⁻³. The thermal anneal also drives in and electrically activates the dopants of the shallow source/drain extensions 92, 94, optional halo regions, and source/drain regions 106, 108.

The emitter-base junction 122, which is defined at the location of coextensive portions of the base region 48 and emitter region 78 for which the net doping concentration is null or zero, is collectively defined by a top segment 124 and sidewall segments 126, 128 joined by the top segment 124. Hence, the emitter-base junction 122 comprises a three-dimensional, non-planar feature of the bipolar junction transistor 125. The emitter-base junction 122 (as well as the collector, base, and emitter regions 34, 48, 78 and collector-base junction 50) has a length slightly greater than the height of fin structure 16 at sidewall 23, plus the width of fin structure 16 across the top surface 20, plus the height of fin structure 16 at sidewall 25. The base region 48, emitter region 78, and emitter-base junction 122 are continuous regions of semiconductor material. The segment 124 and sidewall segments 126, 128 of emitter-base junction 122 extend adjacent to the top segment 20 and the sidewall segments 23, 25 of the fin structure 16.

Although illustrated as having an NPN doping configuration for the collector region 34, base region 48, and emitter region 78, the fabrication of the bipolar junction transistor 125 may be modified to provide a PNP doping configuration for the collector region 34, base region 48, and emitter region 78 as understood by a person having ordinary skill in the art. Similarly, the conductivity type of the source/drain extensions 92, 94, optional halo regions, and source/drain regions 106, 108 of the fin-type field effect transistor 135 may be selected to provide an n-channel device or a p-channel device.

After this fabrication stage, the bipolar junction transistor 125 and field effect transistor 135 are in a condition suitable for forming electrical contacts.

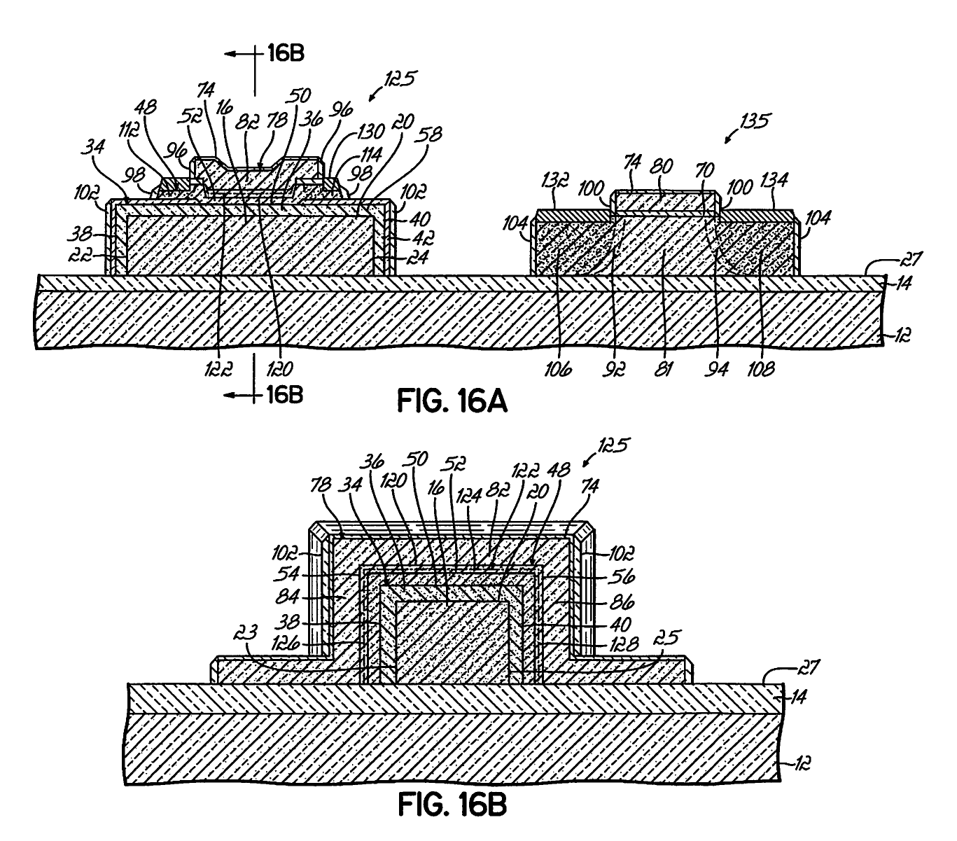

With reference to FIGS. 16A and 16B in which like reference numerals refer to like features in FIGS. 15A and 15B and at a subsequent fabrication stage, a contact region 130 is formed on a top surface of the contact pad 88 of the base region 48. Contact region 130 provides a low resistance contact to the semiconductor material constituting the base region 48. Contact regions 132, 134 are also formed on the source/drain regions 106, 108, respectively. Contact regions 132, 134 provide low resistance contacts to the constituent material of the gate electrode 80.

Contact regions 130, 132, 134 may be, for example, self-aligned silicide or salicide contacts formed using a conventional silicidation or salicidation process well known to a person having ordinary skill in the art, which includes forming a layer of refractory metal, such as titanium (Ti), cobalt (Co), tungsten (W), or nickel (Ni), on the silicon-containing semiconductor material comprising the base region 34 and heating the metal/silicon-containing material stack by, for example, a rapid thermal annealing process to transform the stack to form a silicide. Thereafter, any non-reacted refractory metal is removed utilizing a conventional wet chemical etchant. The silicidation may be conducted in an inert gas atmosphere or in a nitrogen-rich gas atmosphere.

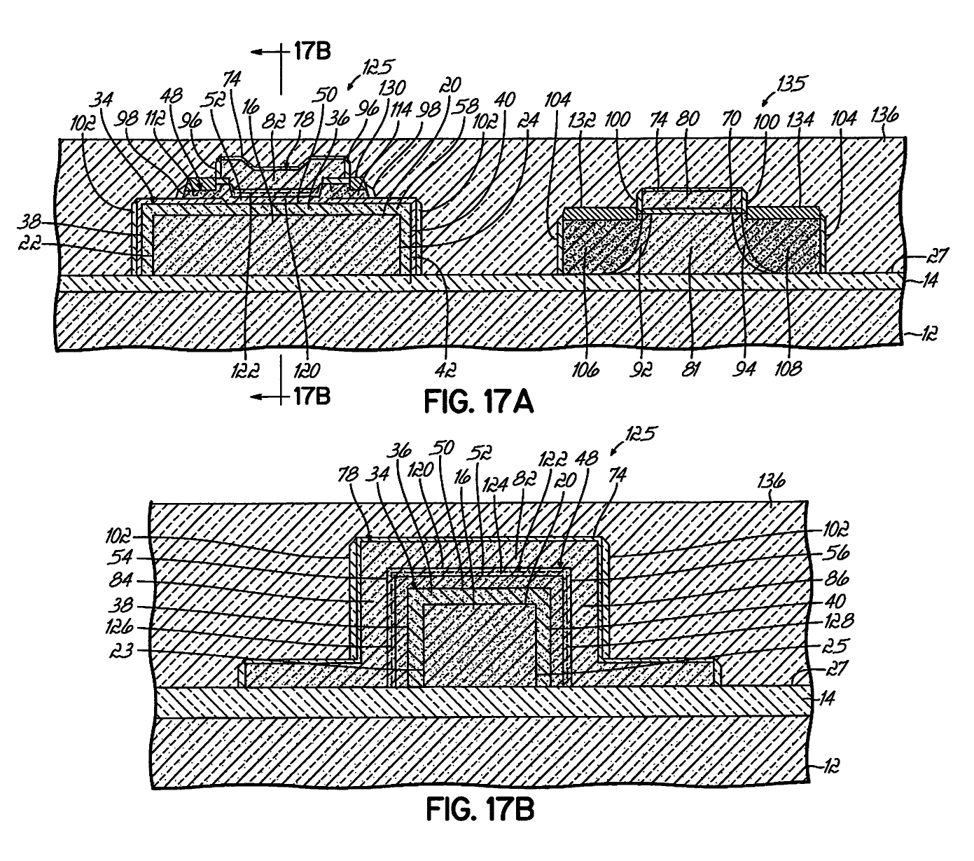

With reference to FIGS. 17A and 17B in which like reference numerals refer to like features in FIGS. 16A and 16B and at a subsequent fabrication stage, a blanket layer 136 of an insulating material is applied across the bipolar junction transistor 125 and field effect transistor 135 and planarized by a conventional planarization process like chemical mechanical planarization (CMP). The insulating material of the blanket layer 136, which provides an interlayer dielectric for contact formation, may be composed of a spin-on glass (SOG) material applied by coating the SOI wafer 10 with the SOG material in liquid form, spinning the SOI wafer 10 at high speeds to uniformly distribute the liquid on the surface by centrifugal forces, and baking at a low temperature to solidify the SOG material. Alternatively, the insulating material of the blanket layer 136 may include multiple coatings of different dielectric materials as understood by a person having ordinary skill in the art.

Another particularly advantageous dielectric material that may be employed to form the insulating material of the blanket layer 136 is diamond-like carbon or diamond deposited by a thermal or plasma CVD process, which may improve heat dissipation because of diamond's relatively high thermal conductivity. The large surface area of the bipolar junction transistor 125 promotes efficient thermal dissipation to the blanket layer 136 in comparison to traditional planar constructions. This ability to dissipate heat may be important for effectively cooling the bipolar junction transistor 125 when the integrated circuit is powered and operating. Other dielectric materials having a high thermal conductivity and a low electrical conductivity may be employed to form the insulating material of the blanket layer 136 as understood by a person having ordinary skill in the art.

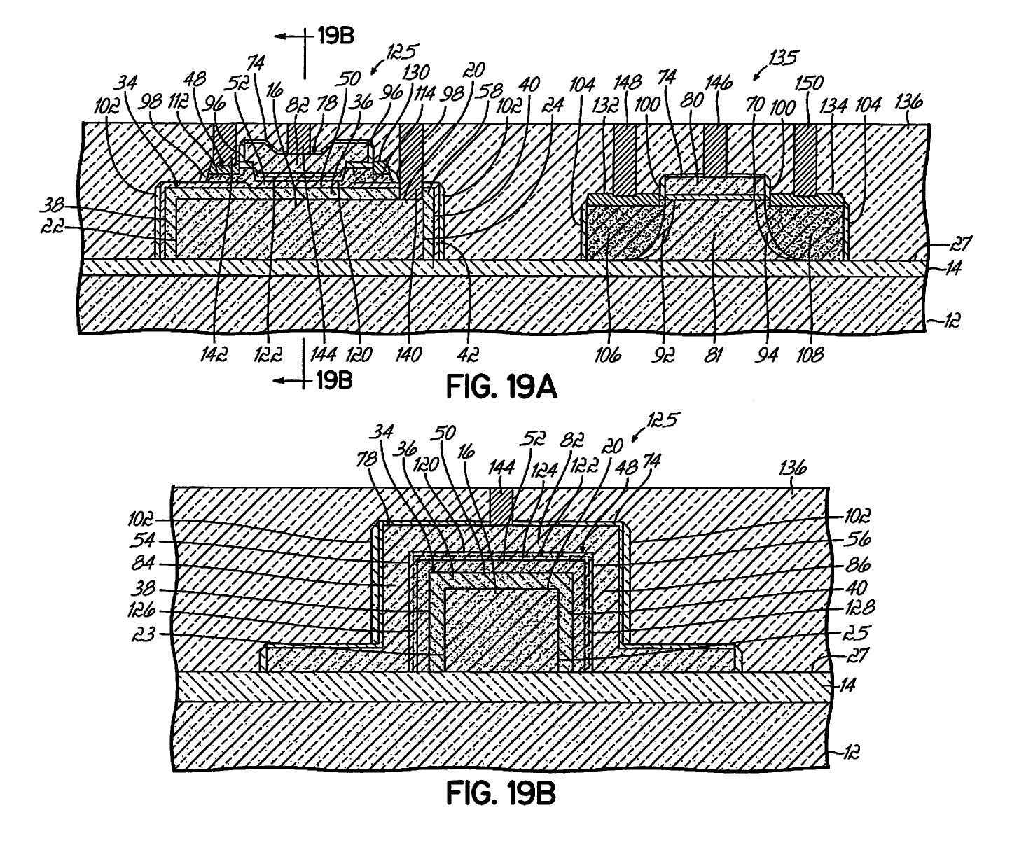

With reference to FIGS. 18, 19, and 19A in which like reference numerals refer to like features in FIGS. 17A and 17B and at a subsequent fabrication stage, the blanket layer 136 of insulating material is then modified in a conventional manner to define a contact layer for the bipolar junction transistor 125 and the field effect transistor 135. Specifically, electrical contacts 140, 142, 144 are fabricated that extend through the blanket insulating layer 136 to the collector region 34, base region 48, and emitter region 78, respectively, of the bipolar junction transistor 125. Electrical contacts 146, 148, 150 are also fabricated that extend through the blanket insulating layer 136 to gate electrode 80, source/drain region 106, and source/drain region 108 of the field effect transistor 135. The electrical contacts 140, 142, 144, 146, 148, 150 may be formed by lithographically patterning via holes in the blanket insulating layer 136, depositing a conductive material using a conventional process, such as CVD or plating, and planarizing the deposited conductive material with a conventional planarization process, like CMP, to remove the overburden on insulating layer 136 and leave behind electrically-isolated plugs of conductive material in the via holes. Conductive materials suitable for the electrical contacts 140, 142, 144, 146, 148, 150 may include, but are not limited to, metals such as tungsten, copper, aluminum, silver, gold, and alloys thereof.

Electrical contact 140 extends through the blanket insulating layer 136 and the dielectric layer 42 to the depth of the collector region 34 and is electrically coupled with the peripheral contact pad 58 of the collector region 34. The contact pad 58 of collector region 34 is not overlapped by the base region 48 and, thus, does not participate in forming the emitter-base junction 122. Contact pad 58 of collector region 34 also extends laterally of the emitter region 78 so that the emitter region 78 does not occlude the path for establishing the contact 140. Electrical contact 142 extends through the blanket insulating layer 136 to the depth of the peripheral contact pad 88 of the base region 48 and is electrically coupled with the contact region 130 of, for example, salicide. Electrical contact 144 extends through the blanket insulating layer 136 and the cap layer 74 to the depth of the emitter region 78 and is electrically coupled with the emitter region 78.

As best shown in FIG. 19A, the collector region 34, base region 48, and emitter region 78, as well as junctions 50, 122, of the bipolar junction transistor 125 each wrap about the top surface 20 and sidewalls 23, 25 of the fin structure 16 so that each extends about three sides of the fin structure 16 in a non-planar construction. The emitter-base junction 122 also wraps about the top surface 20 and sidewalls 23, 25 of the fin structure 16, which significantly increases the bipolar junction area and current per unit area of silicon real estate on the SOI wafer 10. Instead of forming the collector region 34, base region 48, emitter region 78 and emitter-base junction 122 on planar surfaces, as done during the fabrication of conventional bipolar junction transistors, bipolar junction transistor 125 utilizes the relatively large surface area on fin structure 16 of semiconductor material to provide a three-dimensional, non-planar device structure. As a result, the emitter-base junction 122 is not limited by the planar surface area of a conventional handle substrate (not shown). The collector region 34, base region 48, and emitter region 78 of the bipolar junction transistor 125 have a tiered configuration for the respective structural peripheral edges that facilitates forming contacts 140, 142, 144 by exposing contact pad 88 of the base region 48 peripherally of the emitter region 78 and by exposing contact pad 58 of the collector region 34 peripherally of the base region 48.

The device structure comprising the bipolar junction transistor 125 and the field effect transistor 135 strategically relies on block masks during certain fabrication steps for mutual isolation so that these steps are not shared. Other fabrication steps are shared during the fabrication process for seamless integration that reduces the process complexity by limiting the gross number of process steps required to form the device structures of the invention.

References herein to terms such as “vertical”, “horizontal”, etc. are made by way of example, and not by way of limitation, to establish a frame of reference. The term “horizontal” as used herein is defined as a plane parallel to the top surface 20 of fin structure 16 and the top surface 26 of fin structure 18, regardless of its actual three-dimensional spatial orientation. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The fabrication of the semiconductor structure herein has been described by a specific order of fabrication stages and steps. However, it is understood that the order may differ from that described. For example, the order of two or more fabrication steps may be switched relative to the order shown. Moreover, two or more fabrication steps may be conducted either concurrently or with partial concurrence. In addition, various fabrication steps may be omitted and other fabrication steps may be added. It is understood that all such variations are within the scope of the present invention. It is also understood that features of the present invention are not necessarily shown to scale in the drawings.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept.

What is claimed is:

1. A semiconductor device structure on an insulating layer, comprising:
a first semiconductor body having a top surface and sidewalls extending from said top surface toward the insulating layer, said first semiconductor body including a source region, a drain region, and a channel region between said source region and said drain region;
a gate electrode overlapping said channel region of said first semiconductor body;
a second semiconductor body having a top surface and first and second sidewalls extending from said top surface toward the insulating layer; and
a first region of a first semiconductor material with a first conductivity type and a second region of a second semiconductor material with a second conductivity type, said first and second regions disposed on at least one of said top surface, said first sidewall, or said second sidewall of said second semiconductor body with an at least partially overlapping relationship to define a first junction extending between said first and second regions adjacent to the at least one of said top surface, said first sidewall, or said second sidewall of said second semiconductor body.

2. The semiconductor device structure of claim 1 wherein said first region comprises an emitter region of a bipolar junction transistor and said second region comprises a base region of the bipolar junction transistor.

3. The semiconductor device structure of claim 1 wherein said first region comprises a collector region of a bipolar junction transistor and said second region comprises a base region of the bipolar junction transistor.

4. The semiconductor device structure of claim 1 of claim 1 further comprising:
a blanket insulating layer covering said first and second semiconductor bodies, said gate electrode, and said first and second regions.

5. The semiconductor device structure of claim 4 further comprising:
a plurality of conductor-filled vias extending through said blanket insulating layer to contact said first and second regions, said gate electrode, and said source and drain regions.

6. The semiconductor device structure of claim 4 wherein said blanket insulating layer comprises diamond.

7. The semiconductor device structure of claim 1 wherein said first and second regions are disposed on said top surface and at least one of said first and second sidewalls of said second semiconductor body such that said first junction further extends between said first and second regions adjacent to said top surface and said at least one of said first sidewall or second sidewall of said second semiconductor body.

8. The semiconductor device structure of claim 1 wherein said gate electrode is disposed on said top surface and said first and second sidewalls of said first semiconductor body such that said first junction further extends between said first and second regions adjacent to said top surface and said first and second sidewalls of said second semiconductor body.

9. The semiconductor device structure of claim 1 wherein said first and second sidewalls of said first semiconductor body intersect the insulating layer, and said first and second sidewalls of said second semiconductor body intersect the insulating layer.

10. The semiconductor device structure of claim 9 wherein at least one of said first and second sidewalls of said first semiconductor body is separated from at least one of said first and second sidewalls of said second semiconductor body by dielectric material.

11. The semiconductor device structure of claim 1 further comprising:
a third region having said first conductivity type, said third region disposed on at least said top surface of said semiconductor body in an at least partially overlapping relationship with said second region to define a second junction extending between said second and third regions adjacent to at least said top surface of said semiconductor body.

12. The semiconductor device structure of claim 1 wherein said source region, said drain region, said channel region, and said gate electrode comprise a fin-type field effect transistor.

13. A method of fabricating a semiconductor device structure on an insulating layer, the method comprising:
forming electrically-isolated first and second semiconductor bodies each having a top surface and first and second sidewalls extending from the top surface toward the insulating layer;
forming a source region and a drain region in the first semiconductor body;
forming a gate electrode that overlaps a channel region of the first semiconductor body positioned between the source region and the drain region;
forming a first region of a first semiconductor material having a first conductivity type and disposed on at least one of the top surface, the first sidewall, or the second sidewall of the second semiconductor body; and
forming a second region of a second semiconductor material having a second conductivity type that is at least partially coextensive with the first region to define a first junction.

14. The method of claim 13 wherein forming the first and second semiconductor bodies further comprises:
patterning a continuous layer of monocrystalline semiconductor material carried on the insulating layer to form the first and second sidewalls of the first and second semiconductor bodies.

15. The method of claim 13 further comprising:
forming a third region of the first conductivity type on at least one of the top surface, the first sidewall, or the second sidewall of the second semiconductor body and at least partially coextensive with the first region to define a first junction.

16. The method of claim 13 wherein forming the source and drain regions further comprises:
covering the first semiconductor body with a block mask while the first and second regions are formed.

17. The method of claim 13 further comprising:
covering the second semiconductor body with a block mask; and
forming a gate dielectric that overlaps the channel region of the first semiconductor body before the gate electrode is formed and while the block mask covers the second semiconductor body.

18. The method of claim 17 further comprising:
stripping the block mask from the second semiconductor body; and
depositing and patterning a layer of a third semiconductor material layer having the second conductivity type to simultaneously form the gate electrode and the second region.

19. The method of claim 17 further comprising:
stripping the block mask from the second semiconductor body; and
depositing and patterning a layer of a third semiconductor material layer having the first conductivity type to simultaneously form the gate electrode and a third region that is at least partially coextensive with the second region to define a second junction.

20. The method of claim 17 further comprising:
depositing a dielectric layer on the first region; and
forming an opening in the dielectric layer extending to the first region along at least the top surface of the semiconductor body before the layer of the third semiconductor material layer is deposited and patterned to form the second region in the opening.

21. The method of claim 13 further comprising:
patterning a layer of a third semiconductor material layer having the second conductivity type to simultaneously form the gate electrode and the second region.

22. The method of claim 13 wherein the second region is disposed between the first region and the second semiconductor body, and further comprising:
covering the second semiconductor body with a block mask; and
forming a region in the first semiconductor body having a conductivity different from the first conductivity type.

23. The method of claim 13 further comprising:
covering the first and second semiconductor bodies, the source and drain regions, the gate electrode and the first and second regions with a blanket layer including diamond.

24. The method of claim 23 further comprising:
forming conductor-filled vias extending through the blanket layer to establish electrical contacts with the first and second semiconductor bodies, the source and drain regions, the gate electrode and the first and second regions.

25. The method of claim 13 wherein the first region comprises one of an emitter region or a base region of 1 bipolar junction transistor, the second region comprises the other of the base region or the emitter region, and the source region, the drain region, the channel region, and the gate electrode comprise a fin-type field effect transistor.
